(19) United States
(12) Patent Application Publication
(10) Pub. No.: US 2004/0224481 A1
(43) Pub. Date: Nov. 11, 2004

(54) Semiconductor devices, manufacturing methods therefor, circuit substrates and electronic devices

(75) Inventor: Hiroyuki Tomimatsu, Sakata-shi (JP)

Correspondence Address: OLIFF & BERRIDGE, PLC, P.O. BOX 19928, ALEXANDRIA, VA, 22320, US

(73) Assignee: SEIKO EPSON CORPORATION, Tokyo (JP)

(21) Appl. No.: 10/770,468

(22) Filed: Feb. 4, 2004

(30) Foreign Application Priority Data
Feb. 24, 2003 (JP) 2003-045876

(51) Int. Cl. H01L 21/30

(52) U.S. Cl. 438/455

(57) ABSTRACT

The invention provides semiconductor devices that are excellent in manufacturing efficiency, and provides highly reliable semiconductor devices, circuit substrates and electronic equipment. A method of manufacturing a semiconductor device in accordance with the present invention includes: providing liquid resin on a first semiconductor chip, which is mounted on a substrate having wiring patterns; mounting a second semiconductor chip over the first semiconductor chip through the liquid resin; and hardening the liquid resin to form a spacer between the first semiconductor chip and the second semiconductor chip, and to fix the first and second semiconductor chips together.

### BACKGROUND OF THE INVENTION

1. Field of Invention

The present invention relates to semiconductor devices, manufacturing methods thereof, circuit substrates and electronic devices.

2. Description of Related Art

A related art semiconductor device is manufactured by stacking a plurality of semiconductor chips in layers through spacers. To increase the efficiency in manufacturing semiconductor devices, the number of steps in the process of manufacturing semiconductor devices should preferably be reduced as much as possible, and the material used therefore should also preferably be reduced.

### SUMMARY OF THE INVENTION

The present invention provides a method of manufacturing semiconductor devices, which has a high production efficiency. The invention also provides semiconductor devices, circuit substrates and electronic devices which are highly reliable.

(1) A method of manufacturing a semiconductor device in accordance with the present invention, includes: providing liquid resin on a first semiconductor chip having a plurality of pads, which is mounted on a substrate having wiring patterns; mounting a second semiconductor chip over the first semiconductor chip through the liquid resin, in an overlapping manner and separated from the pads; and hardening the liquid resin to form a spacer between the first semiconductor chip and the second semiconductor chip, and to fix the first and second semiconductor chips together. According to the present invention, by hardening the liquid resin, the spacer is formed, and the first and second semiconductor chips are fixed together as well. For this reason, a step of forming a spacer and a step of fixing the first and second semiconductor chips together can be simultaneously conducted, and therefore the semiconductor device can be effectively manufactured.

(2) In the method of manufacturing a semiconductor device, the spacer may be formed such that the first semiconductor chip is generally in parallel with the second semiconductor chip. Consequently, the first semiconductor chip and the second semiconductor chip would become difficult to contact each other, such that a highly reliable semiconductor device can be manufactured.

(3) In the method of manufacturing a semiconductor device, the liquid resin may include a plurality of balls, such that the balls may be present between the first and second semiconductor chips. As a result, the first semiconductor chip and the second semiconductor chip become difficult to come in contact with each other, such that a highly reliable semiconductor device can be manufactured.

(4) In the method of manufacturing a semiconductor device, the balls may be elastic. As a result, the balls can reduce or prevent damage on the semiconductor chips, and therefore a highly reliable semiconductor device can be manufactured.

(5) The method of manufacturing a semiconductor device may further include electrically connecting the pads on the first semiconductor chip and the wiring patterns with wires, before the mounting of the second semiconductor chip.

(6) In the method of manufacturing a semiconductor device, a dielectric layer may be formed on a surface of the second semiconductor chip, which faces the first semiconductor chip. As a result, short-circuit of the second semiconductor chip with the first semiconductor chip or with the wires can be reduced or prevented, such that highly reliable semiconductor devices can be manufactured.

(7) The method of manufacturing a semiconductor device may further include forming a sealing section on the substrate to seal the first and second semiconductor chips.

(8) A semiconductor device in accordance with the present invention is fabricated by the method of manufacturing a semiconductor device described above.

(9) A circuit substrate in accordance with the present invention includes the semiconductor device described above mounted thereon.

(10) An electronic equipment in accordance with the present invention includes the semiconductor device described above.

### BRIEF DESCRIPTION OF THE DRAWINGS

FIG. 1 is a schematic showing a method of manufacturing a semiconductor device in accordance with an exemplary embodiment of the present invention;

FIG. 2 is a schematic showing the method of manufacturing a semiconductor device in accordance with the exemplary embodiment of the present invention;

FIG. 3 is a schematic showing the method of manufacturing a semiconductor device in accordance with the exemplary embodiment of the present invention;

FIG. 4 is a schematic showing the method of manufacturing a semiconductor device in accordance with the exemplary embodiment of the present invention;

FIG. 5 is a schematic showing the method of manufacturing a semiconductor device in accordance with the exemplary embodiment of the present invention;

FIG. 6 is a schematic showing the method of manufacturing a semiconductor device in accordance with the exemplary embodiment of the present invention;

FIG. 7 is a schematic showing the method of manufacturing a semiconductor device in accordance with the exemplary embodiment of the present invention;

FIG. 8 is a schematic showing the method of manufacturing a semiconductor device in accordance with the exemplary embodiment of the present invention;

FIG. 9 is a schematic showing the method of manufacturing a semiconductor device in accordance with the exemplary embodiment of the present invention;

FIG. 10 is a schematic showing a circuit substrate having a semiconductor device in accordance with an exemplary embodiment of the present invention mounted thereon;

FIG. 11 is a schematic showing an electronic device having a semiconductor device in accordance with an exemplary embodiment of the present invention; and

FIG. 12 is a schematic showing an electronic device having a semiconductor device in accordance with an exemplary embodiment of the present invention.

### DETAILED DESCRIPTION OF PREFERRED EMBODIMENTS

Exemplary embodiments of the present invention are described below with reference to the accompanying drawings. However, the present invention is not limited to the exemplary embodiments described below.

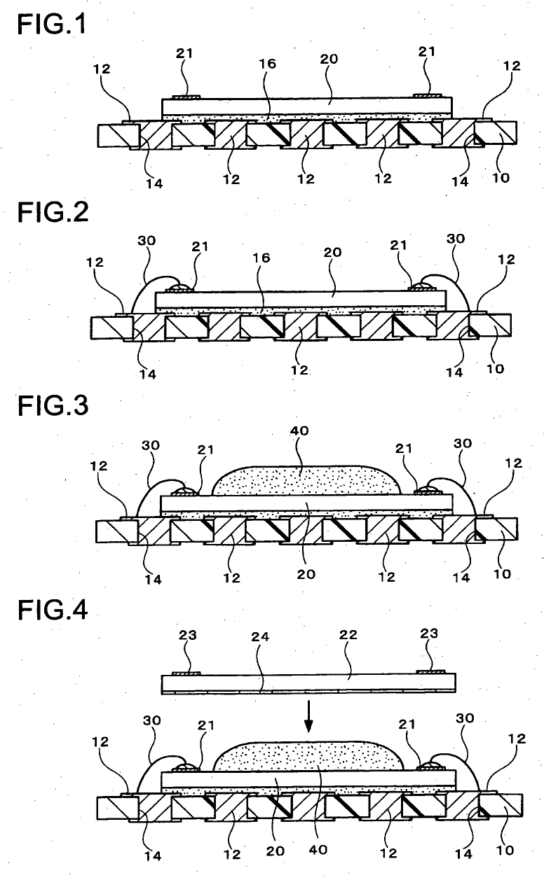

FIG. 1 through FIG. 9 are schematics describing a method of manufacturing a semiconductor device in accordance with an exemplary embodiment of the present invention. First, as indicated in FIG. 1, a first semiconductor chip 20 is mounted on a substrate 10.

The substrate 10 may be composed of material that is either organic (such as polyimide substrate or the like) or inorganic (such as ceramics substrate, glass substrate or the like), or may be formed from a compound structure (such as glass epoxy substrate or the like) of these materials. The planar shape of the substrate 10 is not particularly limited, and may be in a rectangular configuration. The substrate 10 may be formed from either a single layer or multiple-layer substrate.

The substrate 10 includes a wiring pattern 12 formed from a plurality of wirings. A plurality of penetrated holes 14 are formed in the substrate 10 to electrically connect one surface and the other surface thereof. The penetrated holes 14 may be embedded with conductive material, or may be through holes having internal wall surfaces being processed with plating. By so doing, the two surfaces of the substrate 10 can be electrically connected.

The shape of the first semiconductor chip 20 is not particularly limited, and may be in a generally rectangular solid (including cubic) configuration. The first semiconductor chip 20 includes an integrated circuit composed of transistors and memory elements (not shown) formed therein. The first semiconductor chip 20 includes a plurality of pads 21 that are electrically connected to the integrated circuit. The pads 21 may be formed in end sections of the surface of the first semiconductor chip 20, along two or four of the sides of its exterior configuration, or may be formed in a central area of the surface. The pads 21 may be formed from aluminum metal or copper metal. Also, a passivation film (not shown) may be formed over the first semiconductor chip 20 in a manner to avoid central portions of the pads 21. The passivation film may be composed of, for example, SiO₂, SiN, polyimide resin or the like.

In the present exemplary embodiment, the first semiconductor chip 20 may be mounted in a manner that a surface thereof on the opposite side of the surface having the pads 21 formed thereon faces the substrate 10. The first semiconductor chip 20 may be affixed to the substrate with adhesive 16. In this instance, the adhesive 16 that is dielectric may be used.

In the present exemplary embodiment, as indicated in FIG. 1, a semiconductor device may be manufactured by mounting a single first semiconductor chip 20 on a single substrate 10. However, a plurality of semiconductor chips 20 may be mounted on one substrate, such that a plurality of semiconductor devices may be collectively manufactured.

The method of manufacturing a semiconductor device in accordance with the present exemplary embodiment includes electrically connecting the first semiconductor chip 20 and the wiring pattern 12. As indicated in FIG. 2, wires 30 may be used for electrical connection of the first semiconductor chip 20 and the wiring pattern 12. More specifically, by a wire bonding process, wires 30 to electrically connect the pads 21 and the wiring pattern 12 may be formed, to electrically connect the first semiconductor chip 20 and the wiring pattern 12. The wire bonding process may be conducted by any related art or known method. For example, a ball bump method may be used to form the wires 30. Also, the material of the wires 30 is not particularly limited, and for example, gold wires may be used. The wire bonding process may be performed after the process of providing liquid resin 40 described below, and may preferably be conducted before the mounting of a second semiconductor chip 22. By conducting it before the process of mounting the second semiconductor chip 22, the wire bonding can be conducted in a state in which the pads 21 are exposed, such that the wires 30 can be readily formed.

The method of manufacturing a semiconductor device in accordance with the present exemplary embodiment includes, as indicated in FIG. 3, providing the liquid resin 40 on the first semiconductor chip 20. The liquid resin 40 becomes a spacer 50 as it hardens. The liquid resin 40 may be dielectric. By dripping (potting) the liquid resin 40 by using a dispenser, the liquid resin 40 may be provided on the first semiconductor chip 20.

The method of manufacturing a semiconductor device in accordance with the present exemplary embodiment includes, as indicated in FIG. 4, mounting a semiconductor chip 22 on the first semiconductor chip 20. The second semiconductor chip 22 may be mounted over the first semiconductor chip 20 through the liquid resin 40 in a manner that it is separated from and overlap the pads 21. The contents described with respect to the first semiconductor chip 20 may be applied to the second semiconductor chip 22. For example, the second semiconductor chip 22 may include a plurality of pads 23. Also, the size of the second semiconductor chip 22 is not particularly limited, and may be generally the same as the first semiconductor chip 20. The second semiconductor chip 22 may be mounted in a manner such that its surface facing the first semiconductor chip 20 does not come in contact with the wires 30. In other words, the second semiconductor chip 22 may be mounted in a manner such that the height of the spacer 50 becomes higher than the loop height of the wires 30. As a result, short-circuit between the wires 30 and the second semiconductor chip 22 can be reduced or prevented. Also, the second semiconductor chip 22 may be mounted in a manner that the first semiconductor chip 20 and the second semiconductor chip 22 are generally in parallel with each other. As a result, short-circuit between the first and second semiconductor chips 20 and 22 can be reduced or prevented. A dielectric layer 24 may be formed on the surface of the second semiconductor chip 22 which opposes the substrate 10. As a result, short-circuit between the second semiconductor chip 22 and the first semiconductor chip 20 or the wires 30 can be reduced or prevented, such that a highly reliably semiconductor device can be manufactured. In the method of manufacturing the semiconductor device in accordance with the present exemplary embodiment, the liquid resin 40 is hardened to fix the first semiconductor chip 20 and the second semiconductor chip 22 together. Accordingly, whether or not the dielectric layer 24 has a bonding force is not particularly concerned.

The method of manufacturing a semiconductor device in accordance with the present invention includes hardening the liquid resin 40 to form a spacer 50 between the first semiconductor chip 20 and the second semiconductor chip 22, and to fix the first and second semiconductor chips 20 and 22 together (see FIG. 5). More specifically, resin whose adhesive strength appears at it hardens may be used as the liquid resin 40. The process to harden the liquid resin 40 may differ depending on the type of the liquid resin. For example, heat treatment or ultraviolet ray irradiation treatment may be conducted. In the method of manufacturing a semiconductor device in accordance with the present invention, the liquid resin 40 is hardened to thereby form the spacer 50, and to fix the first and second semiconductor chips 20 and 22 together. In other words, the forming of the spacer 50 and the step of fixing the first and second semiconductor chips 20 and 22 are collectively performed. For this reason, the semiconductor device can be effectively manufactured. Also, without using another adhesive, the first and second semiconductor chips can be fixed together, such that the material cost can be reduced.

The spacer 50 may be formed such that the first semiconductor chip 20 and the second semiconductor chip 22 are generally in parallel with each other. As a result, it would become difficult to contact the first and second semiconductor chips 20 and 22 with each other, such that a highly reliable semiconductor device can be manufactured. Also, the spacer 50 may preferably have a height that does not cause short-circuit between the second semiconductor chip 22 and the wires 30 or the first semiconductor chip 20. The height of the spacer 50 may be controlled by the amount of the liquid resin 40 used and/or the pressure to be applied to the second semiconductor chip 22. When the second semiconductor chip 22 has a dielectric layer, the height of the spacer 50 can be reduced because short-circuit does not occur even when the second semiconductor chip 22 contacts the wires 30, such that a semiconductor device that is thin and excellent in mountability can be manufactured.

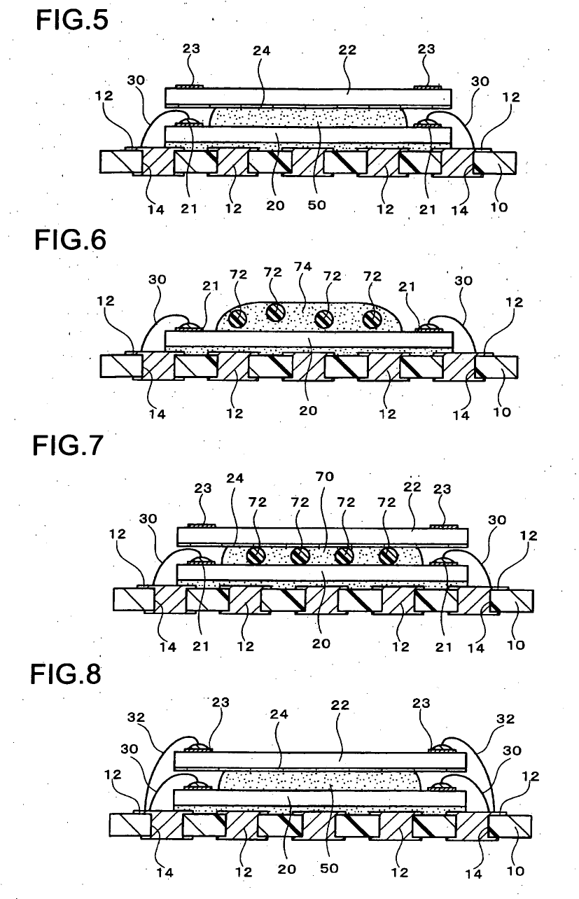

As a modified example, a semiconductor device may be manufactured, using liquid resin 74 containing a plurality of balls 72. More specifically, after providing the liquid resin 74 on the first semiconductor chip 20 (see FIG. 6), the second semiconductor chip 22 is mounted such that the balls 72 are present between the first and second semiconductor chips 20 and 22. Then, by hardening the same, a spacer 70 having the plural balls 72 contained therein may be formed (see FIG. 7). As a result, the disposition of the second semiconductor chip 22 is restricted by the balls 72, such that the second semiconductor chip 22 can be readily mounted in a manner to be parallel with the first semiconductor chip 20, and therefore a highly reliable semiconductor device can be effectively fabricated. The balls 72 may be dielectric. For example, the balls 72 may be resin balls or rubber balls. Also, the balls 72 may be elastic. In this case, the balls 72 can reduce or prevent damage on the semiconductor chips. Also, the spacer 70 may be formed to have a height that is generally the same as the diameter of the balls 72. In other words, a semiconductor device in accordance with the present exemplary embodiment may be manufactured using balls having a diameter that is generally the same as the designed height of the spacer 70.

The method of manufacturing a semiconductor device in accordance with the present invention may include, as indicated in FIG. 8, electrically connecting the pads 23 of the second semiconductor chip 22 and the wiring pattern 12 with wires 32. The wires 32 may be formed by a process similar to the process that forms the wires 30.

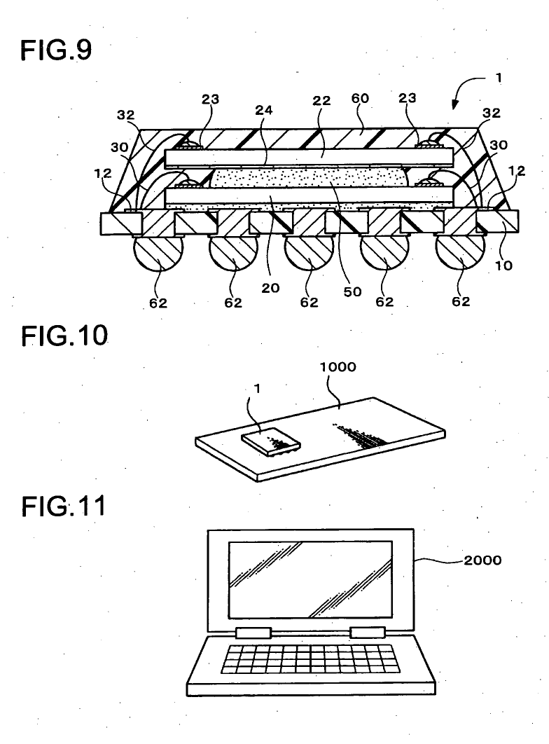

Lastly, through conducting the forming of a sealing section 60 that seals the first and second semiconductor chips 20 and 22 and the forming of external terminals 62, the semiconductor device 1 is manufactured (see FIG. 9). The semiconductor device 1 includes the substrate 10 having the wiring pattern 12, the first and second semiconductor chips 20 and 22 provided over the substrate 10, the spacer 50 provided between the first and second semiconductor chips 20 and 22, and the wires 30 and 32 that electrically connect the electrodes on the first and second semiconductor chips 20 and 22 to the wiring pattern 12. The semiconductor device 1 may further include the resin layer 24 formed on the surface of the second semiconductor chip 22 which opposes the substrate 10, the sealing section 60 and the external terminals 62.

The method of manufacturing the semiconductor device 1 with the first and second semiconductor chips 20 and 22 is described above. However, the present invention is not limited to the above-described method of manufacturing the semiconductor device. In other words, a semiconductor device may be manufactured through mounting another semiconductor chip over the second semiconductor chip 22. In this instance, the other semiconductor chip may be mounted on the second semiconductor chip 22 by steps similar to the mounting of the second semiconductor chip 22 over the first semiconductor chip 20. By these steps, a semiconductor device with a plurality of semiconductor chips including the first and second semiconductor chips 20 and 22 can be manufactured.

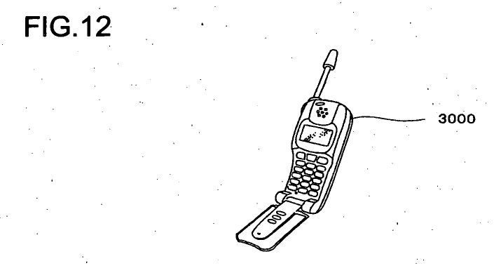

FIG. 10 shows a circuit substrate 1000 on which the semiconductor device 1 manufactured by the method of manufacturing a semiconductor device in accordance with the exemplary embodiment described above is mounted. Also, as exemplary electronic devices including the semiconductor device 1, a notebook type personal computer 2000 is shown in FIG. 11, and a portable telephone 3000 is shown in FIG. 12.

The present invention is not limited to the exemplary embodiments described above, and many modification can be made. For example, the present invention may include compositions that are substantially the same as the compositions described in the exemplary embodiment (for example, a composition that has the same functions, the same methods and the results, or a composition that has the same or similar advantages and results). Also, the present invention includes compositions in which portions not essential in the compositions described in the exemplary embodiment are replaced with others. Also, the present invention includes compositions that achieve the same or similar functions and effects or achieve the same or similar advantages as those of the compositions described in the exemplary embodiment. Furthermore, the present invention includes compositions that include related art or known technology added to the compositions described in the exemplary embodiment.

What is claimed is:

1. A method of manufacturing a semiconductor device, comprising:
providing liquid resin on a first semiconductor chip having a plurality of pads, which is mounted on a substrate having wiring patterns;
mounting a second semiconductor chip over the first semiconductor chip through the liquid resin, in an overlapping manner and separated from the pads; and
hardening the liquid resin to form a spacer between the first semiconductor chip and the second semiconductor chip, and to fix the first and second semiconductor chips together.

2. The method of manufacturing a semiconductor device according to claim 1, further including forming the spacer such that the first semiconductor chip is oriented generally in parallel with the second semiconductor chip.

3. The method of manufacturing a semiconductor device according to claim 2, the liquid resin including a plurality of balls, such that the balls are present between the first and second semiconductor chips.

4. The method of manufacturing a semiconductor device according to claim 3, the balls being elastic.

5. The method of manufacturing a semiconductor device according to claim 1, further comprising electrically connecting the pads on the first semiconductor chip and the wiring patterns with wires, before the mounting of the second semiconductor chip.

6. The method of manufacturing a semiconductor device according to claim 1, further including forming a dielectric layer on a surface of the second semiconductor chip that faces the first semiconductor chip.

7. The method of manufacturing a semiconductor device according to claim 1, further comprising forming a sealing section on the substrate to seal the first and second semiconductor chips.

8. A semiconductor device fabricated by the method of manufacturing a semiconductor device according to claim 1.

9. A circuit substrate, comprising:
the semiconductor device according to claim 8.

10. An electronic equipment, comprising:
the semiconductor device according to claim 8.
